(19) United States
(12) Patent Application Publication
(10) Pub. No.: US 2008/0054396 A1
(43) Pub. Date: Mar. 6, 2008

(54) Semiconductor Device and Fabricating Method Thereof

(76) Inventor: JAE WON HAN, Soowon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/840,771

(22) Filed: Aug. 17, 2007

(30) Foreign Application Priority Data
Aug. 29, 2006 (KR) 10-2006-0082548

(51) Int. Cl. H01L 29/00; H01L 21/44

(52) U.S. Cl. 257/531; 438/598; 257/E29.001; 257/E21.476

(57) ABSTRACT

A semiconductor device and a fabrication method thereof are provided. An inductor device provided with an inductor cell and a second device having a RF device circuit unit are provided next to each other in the same plane and are electrically connected to each other through a connecting electrode.

### CROSS-REFERENCE TO RELATED APPLICATION

The present application claims the benefit under 35 U.S.C. §119 of Korean Patent Application No. 10-2006-0082548, filed Aug. 29, 2006, which is hereby incorporated by reference in its entirety.

### BACKGROUND

An inductor is an element of a circuit which is used for sending and receiving high frequency signals. It is often shaped similar to a coil. Referring to FIG. 1, an inductor 10 can be implemented in a metal pattern with a spiral shape.

Spiral-shaped inductors are often used in RF devices and analog devices. These devices are very important to the growing wireless market, and the characteristics thereof are represented by a Quality factor (Q).

FIG. 2 shows a cross-section of a related art semiconductor device including an inductor.

The related art semiconductor device including an inductor generally has an inductor layer 21 on a RF device circuit unit layer 23. The RF device circuit unit layer 23 is formed, and the inductor layer 21 is formed on the RF device circuit unit layer 23.

Since a metal film used to form the inductor layer 21 is typically very thick, the process has many disadvantages. Also, the process is complicated by the fact that a transistor and a metal wiring are present on the substrate before the inductor layer 21 is formed. When errors occur in the process of fabricating the inductor layer 21, the device formed below it on the substrate is rendered useless.

Thus, there exists a need in the art for an improved semiconductor device and a fabrication process thereof.

### BRIEF SUMMARY

Embodiments of the present invention provide a semiconductor device and a fabricating method thereof.

In an embodiment, a scheme capable of efficiently fabricating a semiconductor device having an inductor is provided. A first device having an inductor cell and a second device having a RF device circuit unit can be fabricated separately and connected. The inductor cell formed in the first device can be electrically connected to the RF device circuit unit formed in the second device using a connecting electrode. Herein, the inductor cell represents an area where an inductor is formed. A metal pattern with a spiral shape can be formed in the inductor cell.

A semiconductor device according to an embodiment can include an inductor device provided with an inductor cell and a second device having an RF device circuit unit. The RF device circuit unit can have a transistor and a wiring. A connecting electrode can electrically connect the inductor cell to the RF device circuit unit.

In an embodiment, an inductor device with an inductor cell and a second device having a RF device circuit unit can be provided. The inductor device and the second device can be positioned next to each other in the same plane and electrically connected.

### BRIEF DESCRIPTION OF THE DRAWINGS

FIG. 1 is a top view of a related art inductor.

FIG. 2 is a cross-sectional view of a related art semiconductor device with an inductor.

FIGS. 3 and 4 are concept views of a System by Interconnection scheme.

FIG. 5 is a top view of an inductor cell according to an embodiment of the present invention.

FIG. 6 is a cross-sectional view of a device with an RF device circuit unit according to an embodiment of the present invention.

FIG. 7 is a cross-sectional view of a semiconductor device according to an embodiment of the present invention.

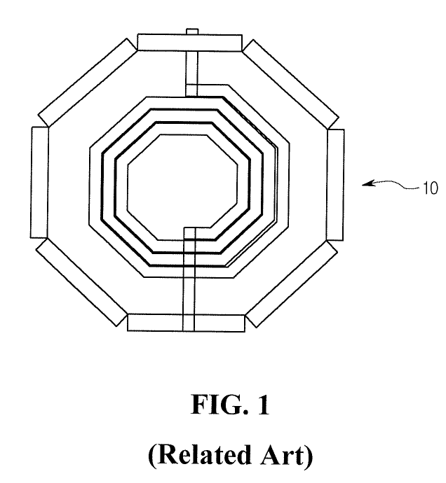

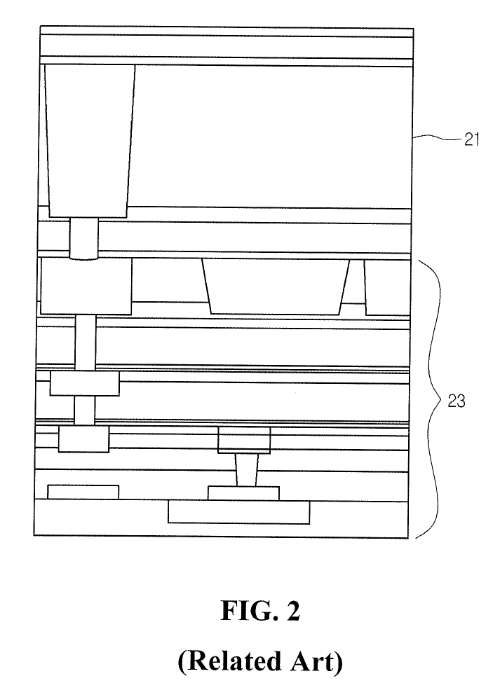

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

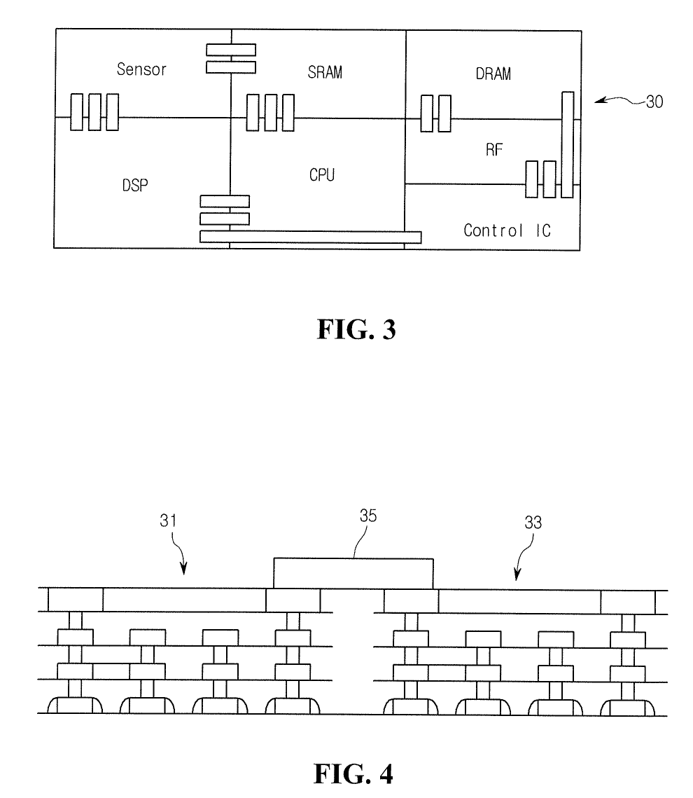

A System by Interconnection (SbI) is a device integrated by interconnecting different unit devices. Devices that can be interconnected in an SbI include a Central Processing Unit (CPU), Static Random Access Memory (SRAM), Dynamic Random Access Memory (DRAM), Flash Memory, Logic Devices, a Power Integrated Circuit (IC), a Control IC, a Sensor Chip, and a Digital Signal Processor (DSP). Other such devices will be apparent to one skilled in the art. Referring to FIG. 3, a device 30 integrated in an SbI scheme is shown. A Sensor Chip, SRAM, DRAM, a DSP, a CPU, an RF device, and a Control IC can be interconnected on a device 30 in an SbI scheme.

Referring to FIG. 4, an SbI scheme can include fabricating a first device 31 and a second device 33. The first device 31 can be connected to the second device 33 through a connecting electrode 35.

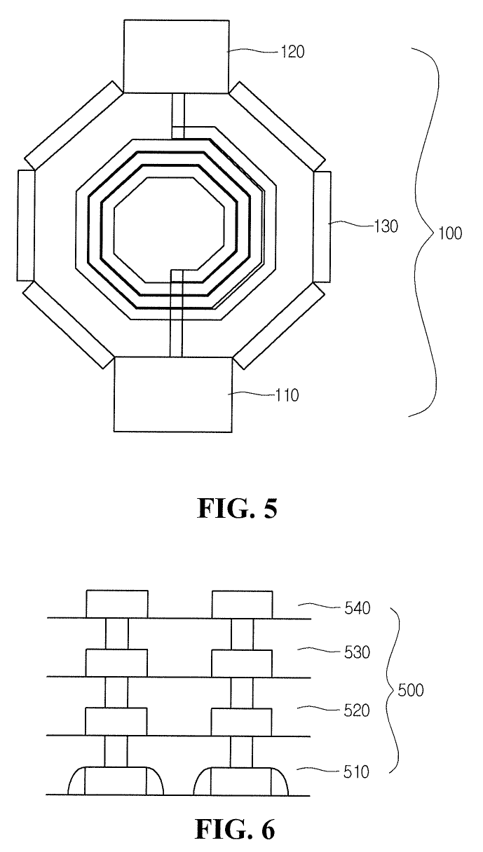

FIG. 5 is a concept view of the device where an inductor cell is formed according to a fabricating method of a semiconductor device of the embodiment.

Referring to FIG. 5, in an embodiment, an inductor device 100 can be fabricated, including a first terminal 110, a second terminal 120, and an inductor cell 130.

An insulating film can be formed on a semiconductor substrate. Patterning for forming the inductor cell 130, the first terminal 110, and the second terminal 120 can be performed. Then, an etching process can be performed. Next, an inductor barrier metal deposition and an inductor metal film filling can be performed. A chemical mechanical polishing process (CMP) can be performed to form the inductor cell 130, the first terminal 110, and the second terminal 120.

The inductor cell 130, the first terminal 110, and the second terminal 120 can each be formed of any reasonable material known in the art. For example, the inductor cell 130, the first terminal 110, and the second terminal 120 can each be formed of tungsten (W), copper (Cu), aluminum (Al), silver (Ag), gold (Au), or any combination thereof. The inductor cell 130 can be deposited by means of chemical vapor deposition (CVD), physical vapor deposition (PVD), Evaporation, electrochemical plating (ECP), or any other reasonable method known in the art. In an embodiment, a barrier metal can be included in the inductor cell 130, the first terminal 110, and the second terminal 120. For example, the barrier metal can be TaN, Ta, TiN, TiSiN, or any other reasonable material known in the art. The barrier metal can be formed by means of CVD, PVD, atomic layer deposition (ALD), or any other reasonable method known in the art.

Additionally, a protective film can be formed on the inductor cell 130.

In an embodiment, of the present invention, a second device, including an RF device circuit unit, can be formed. For example, the RF device circuit unit can include a transistor layer and at least one metal layer.

In particular, referring to FIG. 6, in an embodiment, a second device 500 can be fabricated, including a transistor layer 510, a first metal layer 520, a second metal layer 530, and a third metal layer 540.

The transistor layer 510, the first metal layer 520, the second metal layer 530, and the third metal layer 540 can be used to form an RF device circuit unit for processing signals. Although three metal layers are shown in FIG. 6, the RF device circuit unit can include more or less than three metal layers.

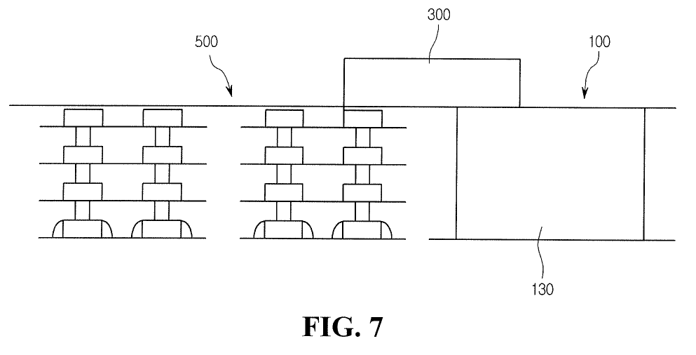

Referring to FIG. 7, the inductor device 100 and the second device 500 can be connected and integrated.

A semiconductor device according to an embodiment of the present invention can include an inductor device 100, a second device 500, and a connecting electrode 300. The connecting electrode 300 can connect an inductor cell 130 of the inductor device 100 to an RF device circuit unit of the second device 500. The connecting electrode 300 can be electrically connected to the inductor cell 130 through a first terminal 110 and a second terminal 120 in the inductor device 100. The connecting electrode 300 can be connected to a top electrode in the uppermost metal layer of the RF device circuit unit of the second device 500. In an embodiment with three metal layers in the RF device circuit unit, the connecting electrode can be connected to a top electrode in the third metal layer 540 of the RF device circuit unit.

The semiconductor device and fabricating method thereof of embodiments of the present invention have several advantages.

The present invention allows for an inductor device and a second device with a transistor and metal wiring to be formed separately. Accordingly, if errors were to occur in the fabrication process of the inductor device, the second device can still be used.

Also, the inductor can be connected such that it is spaced from the RF device circuit unit by means of the connecting electrode. Therefore, crosstalk caused by the inductance can be reduced, thereby improving the characteristics of the semiconductor device.

Moreover, the inductor device can be separately fabricated, making it possible to make an inductor library.

Additionally, the RF device circuit unit can be formed such that it is not affected by the inductor cell process.

Accordingly, embodiments of the present invention lead to a simplified and improved semiconductor device and fabricating method thereof.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
an inductor device comprising an inductor cell;
a second device comprising an RF device circuit unit; and
a connecting electrode which electrically connects the inductor cell to the RF device circuit unit;
wherein the upper surface of the inductor device is in the same plane as the upper surface of the second device.

2. The semiconductor device according to claim 1, wherein the inductor device further comprises:
a first terminal connected to a first end of the inductor cell; and
a second terminal connected to a second end of the inductor cell.

3. The semiconductor device according to claim 2, wherein the connecting electrode is electrically connected to the inductor cell through the first terminal, the second terminal, or both.

4. The semiconductor device according to claim 2, wherein the inductor cell comprises at least one substance selected from the group consisting of W, Cu, Al, Ag, and Au.

5. The semiconductor device according to claim 2, wherein the first terminal comprises at least one substance selected from the group consisting of W, Cu, Al, Ag, and Au.

6. The semiconductor device according to claim 2, wherein the second terminal comprises at least one substance selected from the group consisting of W, Cu, Al, Ag, and Au.

7. The semiconductor device according to claim 1, wherein the second device comprises:
a transistor layer on a semiconductor substrate; and
at least one metal layer formed on the transistor layer.

8. The semiconductor device according to claim 1, wherein the inductor device further comprises a metal pattern with a spiral shape.

9. The semiconductor device according to claim 8, wherein the metal pattern further comprises a barrier metal.

10. The semiconductor device according to claim 9, wherein the barrier metal comprises a material selected from the group consisting of TaN, Ta, TiN, and TiSiN.

11. A method of fabricating a semiconductor device, comprising:
providing an inductor device comprising an inductor cell;
providing a second device comprising an RF device circuit unit; and
disposing the inductor device and the second device to be positioned such that the upper surface of the inductor device is in the same plane as the upper surface of the second device; and
electrically connecting the inductor cell to the RF device circuit unit.

12. The method according to claim 11, wherein electrically connecting the inductor cell to the RF device circuit unit comprises forming a connecting electrode.

13. The method according to claim 11, wherein the inductor device further comprises:
a first terminal connected to a first end of the inductor cell; and
a second terminal connected to a second end of the inductor cell.

14. The method according to claim 13, wherein the connecting electrode is electrically connected to the inductor cell through the first terminal, the second terminal, or both.

15. The method according to claim 13, wherein the inductor cell comprises at least one substance selected from the group consisting of W, Cu, Al, Ag, and Au.

16. The method according to claim 13, wherein the first terminal comprises at least one substance selected from the group consisting of W, Cu, Al, Ag, and Au.

17. The method according to claim 13, wherein the second terminal comprises at least one substance selected from the group consisting of W, Cu, Al, Ag, and Au.

18. The method according to claim 11, wherein the inductor device further comprises a metal pattern with a spiral shape.

19. The method according to claim 18, wherein the metal pattern further comprises a barrier metal.

20. The method according to claim 19, wherein the barrier metal comprises a material selected from the group consisting of TaN, Ta, TiN, and TiSiN.
